(19) United States
(12) Patent Application Publication
(10) Pub. No.: US 2026/0318840 A1
(43) Pub. Date: Oct. 15, 2026

(54) AUTOMATED DEFECT INSPECTION RECIPE GENERATION

(71) Applicant: KLA Corporation, Milpitas, CA (US)

(72) Inventors: Sumant Anurag, San Jose, CA (US); Tommaso Torelli, San Mateo, CA (US); Pranay Deevanapelli, San Jose, CA (US); Vishal Ramakrishna, San Jose, CA (US); Sayi Tummalapalli, San Ramon, CA (US); Bradley Ries, San Jose, CA (US)

(21) Appl. No.: 19/289,988

(22) Filed: Aug. 4, 2025

Related U.S. Application Data
(60) Provisional application No. 63/786,279, filed on Apr. 9, 2025.
(60) Provisional application No. 63/791,521, filed on Apr. 20, 2025.
(60) Provisional application No. 63/791,715, filed on Apr. 21, 2025.
(60) Provisional application No. 63/799,114, filed on May 2, 2025.
(60) Provisional application No. 63/799,104, filed on May 2, 2025.
(60) Provisional application No. 63/799,067, filed on May 2, 2025.

(51) Int. Cl. G01N 21/88; G01N 21/95

(52) U.S. Cl. CPC G01N 21/8806; G01N 21/9501; G01N 2021/8822; G01N 2201/1296

(57) ABSTRACT

An inspection system may receive inspection data for one or more samples from an inspection tool. The system may select values of detection parameters of a detection model with an automated sensitivity tuner, where the detection model can identify potential defect events by comparing inspection data to reference data and applying thresholds. The automated sensitivity tuner may select parameter values to provide selected detection rates of probable defects of interest and probable nuisances. The system can generate a review sampling map with an automated sampling model, which may include review locations to control relative sampling rates of defect types. The system may train a classification model to identify defects of interest based on ground truth data from a review tool. An inspection recipe can be generated that may include the selected detection parameter values and the classification model.

### CROSS-REFERENCE TO RELATED APPLICATIONS

The present application claims the benefit under 35 U.S.C. § 119(e) of U.S. Provisional Application Ser. No. 63/786,279 filed on Apr. 9, 2025; 63/791,521 filed on Apr. 20, 2025; 63/791,715 filed on Apr. 21, 2025; 63/799,114 filed on May 2, 2025; 63/799,104 filed on May 2, 2025; and 63/799,067 filed on May 2, 2025; all of which are incorporated herein by reference in their entireties.

### TECHNICAL FIELD

The present disclosure relates to automated defect inspection in semiconductor manufacturing, and more particularly to an automated recipe workflow for defect inspection.

### BACKGROUND

Defect inspection plays a crucial role in semiconductor manufacturing processes, helping to identify and classify defects that may impact device performance or yield. As semiconductor devices continue to shrink in size and increase in complexity, the challenges associated with defect inspection have grown correspondingly.

Traditional defect inspection workflows often involve multiple iterations of scanning, review, and manual tuning steps. This approach can be time-consuming and resource-intensive, potentially leading to increased cycle times and reduced throughput in high-volume manufacturing environments. Additionally, the expertise required to effectively set up and optimize inspection recipes has become increasingly specialized, creating potential bottlenecks in the manufacturing process. There is therefore a need to develop systems and methods that address the above deficiencies.

### SUMMARY

In some embodiments, an inspection system is provided. The inspection system may include one or more controllers including one or more processors configured to execute program instructions causing the one or more processors to receive inspection data for one or more samples from an inspection tool. The one or more processors may select values of detection parameters of a detection model with an automated sensitivity tuner. The detection model may identify potential defect events on the one or more samples by comparing the inspection data to reference data and applying thresholds associated with the detection parameters. The automated sensitivity tuner may select the values of the detection parameters to provide selected detection rates of probable defects of interest and probable nuisances. The one or more processors may generate a review sampling map with an automated sampling model. The review sampling map may include a set of review locations on the one or more samples to review with a review tool. The one or more processors may train a classification model to identify defects of interest from a set of the potential defect events from the detection model based at least on ground truth data generated by the review tool. The one or more processors may generate an inspection recipe. The inspection recipe may include at least the values of the detection parameters for the detection model selected by the automated sensitivity tuner and the classification model.

In some embodiments, the inspection tool may include an optical inspection tool.

In some embodiments, the inspection tool may include a darkfield optical inspection tool.

In some embodiments, the review tool may include a scanning electron microscope.

In some embodiments, the one or more processors may be further configured to execute program instructions causing the one or more processors to label the potential defect events associated with the one or more samples identified by the detection model with preliminary classes using a neural network model trained on defect data associated with multiple defect types.

In some embodiments, training the classification model to identify the defects of interest from the potential defect events identified by the detection model based at least on the ground truth data may include training the classification model to identify the defects of interest from the potential defect events identified by the detection model based at least on the ground truth data and the preliminary classes from the neural network model.

In some embodiments, the defect data used for training the neural network model may include data from multiple layers.

In some embodiments, the automated sensitivity tuner may include an unsupervised model to classify the inspection data into the probable defects of interest and the probable nuisances. The detection rates of the probable defects of interest and the probable nuisances may be based at least in part on classifications from the unsupervised model.

In some embodiments, the unsupervised model may include a clustering model incorporating an outlier threshold associated with a distance of a particular inspection defect event from a cluster in a multi-dimensional parameter space including at least some of the detection parameters.

In some embodiments, the automated sensitivity tuner may be a supervised model to classify the inspection data into the probable defects of interest and the probable nuisances. The detection rates of the probable defects of interest and the probable nuisances may be based at least in part on classifications from the supervised model.

In some embodiments, selecting the values of the detection parameters to provide selected detection rates of the probable defects of interest and the probable nuisances may include a detection rate of the probable defects equal to or above a first selected percentage.

In some embodiments, selecting the values of the detection parameters to provide selected detection rates of the probable defects of interest and the probable nuisances may further include a detection rate of the probable nuisances equal to or below a second selected percentage.

In some embodiments, the automated sampling model may select the set of review locations to control relative sampling rates of different defect types according to diversity weights associated with at least one of diversity of defect class, diversity of sampled location across an entire sample of the one or more samples, or diversity of samples across different defined regions of the one or more samples.

In some embodiments, the one or more controllers may include an inspection controller associated with the inspection tool. The inspection controller may be configured to select the values of the detection parameters for the detection model with the automated sensitivity tuner. The one or more controllers may include a processing controller communicatively coupled to at least one of the inspection tool or the review tool. The processing controller may be configured to generate the review sampling map with the automated sampling model, train the classification model to identify defects of interest from the set of the potential defect events from the detection model based at least on ground truth data generated by the review tool, and generate the inspection recipe.

In some embodiments, the one or more controllers may include a single controller.

In some embodiments, an inspection system is provided. The inspection system may include an inspection tool configured to generate inspection data for one or more samples. The inspection system may include a review tool having a higher resolution than the inspection tool. The inspection system may include one or more controllers including one or more processors configured to execute program instructions causing the one or more processors to receive inspection data for one or more samples from the inspection tool. The one or more processors may select values of detection parameters of a detection model with an automated sensitivity tuner. The detection model may identify potential defect events on the one or more samples by comparing the inspection data to reference data and applying thresholds associated with the detection parameters. The automated sensitivity tuner may select the values of the detection parameters to provide selected detection rates of probable defects of interest and probable nuisances. The one or more processors may generate a review sampling map with an automated sampling model. The review sampling map may include a set of review locations on the one or more samples to review with a review tool. The one or more processors may train a classification model to identify defects of interest from a set of the potential defect events from the detection model based at least on ground truth data generated by a review tool. The one or more processors may generate an inspection recipe. The inspection recipe may include at least the values of the detection parameters for the detection model selected by the automated sensitivity tuner and the classification model.

In some embodiments, the inspection tool may include an optical inspection tool.

In some embodiments, the inspection tool may include a darkfield optical inspection tool.

In some embodiments, the review tool may include a scanning electron microscope.

In some embodiments, the one or more controllers may include an inspection controller associated with the inspection tool. The inspection controller may be configured to select the values of the detection parameters for the detection model with the automated sensitivity tuner. The one or more controllers may include a processing controller communicatively coupled to at least one of the inspection tool or the review tool. The processing controller may be configured to generate the review sampling map with the automated sampling model, train the classification model to identify defects of interest from the set of the potential defect events from the detection model based at least on ground truth data generated by the review tool, and generate the inspection recipe.

In some embodiments, the one or more controllers may include a single controller.

In some embodiments, an inspection method is provided. The inspection method may include inspecting one or more samples with an inspection tool to generate inspection data. The method may include selecting values of detection parameters for a detection model with an automated sensitivity tuner. The detection model may identify potential defect events on the one or more samples by comparing the inspection data to reference data and applying thresholds associated with the detection parameters. The automated sensitivity tuner may select the values of the detection parameters to provide selected detection rates of probable defects of interest and probable nuisances. The method may include generating a review sampling map with an automated sampling model. The review sampling map may include a set of review locations on the one or more samples to review with a review tool. The method may include reviewing the set of review locations in the review sampling map on the one or more samples with the review tool to generate ground truth data. The ground truth data may include defect classifications of the set of review locations. The method may include training a classification model to identify defects of interest from a set of the potential defect events from the detection model based at least on the ground truth data. The method may include generating an inspection recipe. The inspection recipe may include at least the values of the detection parameters for the detection model selected by the automated sensitivity tuner and the classification model.

In some embodiments, the method may further include labeling the potential defect events associated with the one or more samples identified by the detection model with preliminary classes using a neural network model trained on defect data associated with multiple defect types.

In some embodiments, training the classification model to identify the defects of interest from the potential defect events from the detection model based at least on the ground truth data may include training the classification model to identify the defects of interest from the potential defect events from the detection model based at least on the ground truth data and the preliminary classes from the neural network model.

In some embodiments, the defect data used for training the neural network model may include data from multiple layers.

In some embodiments, the automated sensitivity tuner may include an unsupervised model to classify the inspection data into the probable defects of interest and the probable nuisances. The detection rates of the probable defects of interest and the probable nuisances may be based at least in part on classifications from the unsupervised model.

In some embodiments, the automated sensitivity tuner may be a supervised model to classify the inspection data into the probable defects of interest and the probable nuisances.

In some embodiments, selecting the values of the detection parameters to provide selected detection rates of the probable defects of interest and the probable nuisances may include a detection rate of the probable defects equal to or above a first selected percentage.

In some embodiments, selecting the values of the detection parameters to provide selected detection rates of the probable defects of interest and the probable nuisances may further include a detection rate of the probable nuisances equal to or below a second selected percentage.

In some embodiments, the automated sampling model may select the set of review locations to control relative sampling rates of different defect types according to diversity weights associated with at least one of diversity of defect class, diversity of sampled location across an entire sample of the one or more samples, or diversity of samples across different defined regions of the one or more samples.

In some embodiments, an inspection controller associated with the inspection tool may perform selecting the values of the detection parameters for the detection model with the automated sensitivity tuner. A processing controller communicatively coupled with at least one of the inspection tool or the review tool may perform steps of generating the review sampling map with the automated sampling model, training the classification model to identify defects of interest from the set of the potential defect events from the detection model based at least on ground truth data generated by the review tool, and generating the inspection recipe.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF FIGURES

The numerous advantages of the disclosure may be better understood by those skilled in the art by reference to the accompanying figures.

FIG. 1A illustrates a block diagram of an inspection system, in accordance with some embodiments of the present disclosure.

FIG. 1B illustrates a block diagram of an inspection sub-system, in accordance with one or more embodiments of the present disclosure.

FIG. 1C illustrates a block diagram of a review sub-system, in accordance with one or more embodiments of the present disclosure.

FIG. 2 is a flow diagram illustrating steps performed in a method for automated inspection recipe generation.

FIG. 3 illustrates a receiver operating characteristic (ROC) curve, in accordance with one or more embodiments of the present disclosure.

FIG. 4 illustrates a plot comparing unsupervised and supervised automated sensitivity tuner configurations, in accordance with one or more embodiments of the present disclosure.

FIG. 5 illustrates a comparison of recipe setup time between manual and automated approaches, in accordance with one or more embodiments of the present disclosure.

FIG. 6 illustrates a bar graph comparing manual and automated detection results for three different defect event categories, in accordance with one or more embodiments of the present disclosure.

FIG. 7 illustrates a flowchart of one process for generating an inspection recipe incorporating a dedicated processing controller, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Embodiments of the present disclosure are directed to systems and methods for automated defect inspection recipe generation in semiconductor manufacturing. The systems and methods described herein may accelerate inspection recipe setup while simplifying the process, enabling non-expert users to generate effective inspection recipes without requiring specialized expertise.

An inspection recipe may include one or more models designed to identify and/or classify defects on a sample based on inspection data from an inspection tool (e.g., a tool suitable for high-volume manufacturing (HVM) such as, but not limited to, an optical inspection tool). In many cases, it may be desirable to train or otherwise develop these models based at least in part on ground truth data generated through reviewing defects using a review tool (e.g., a scanning electron microscope (SEM), or the like). However, when developing an inspection recipe, a user may have limited information on relevant data including the specific defect types present, locations of these defects, or parameter values needed to tune the models to distinguish between defects of interest (DOIs) and nuisances. Further, it may generally be desirable to limit or minimize the usage of inspection and/or review tools when developing an inspection recipe to save time and free such tools for other operations.

In embodiments, an automated defect inspection recipe generation process may incorporate several automated steps. These may include a hot scan (e.g., a default scan) to probe the noise floor, an automated sensitivity tuner to tune (e.g., select) detection algorithm parameters associated with an initial defect detection model, generation of a review sampling map to identify locations of key DOIs, and generating (e.g., training) a classification model with at least ground truth data from locations in review sampling map.

The automated workflow may reduce the number of review cycles from multiple iterations to a single review cycle, which may substantially improve the time to recipe as well as free up the review tool for other uses. For example, the automated sensitivity tuner (AST) and/or a discovery sampling process may enable the generation of a single review sampling map for a single review step and avoid inefficient iterative steps. The automated workflow may further reduce the skill level and/or expertise required by a user when generating an inspection recipe. In particular, systems and methods disclosed herein may reduce or eliminate manual tuning of complex algorithms.

In embodiments, the automated workflow may utilize a generalized neural network model, which may be referred to as a mother model, that may be trained on existing data (e.g., historical data) associated with multiple sample layers and defect types. Such a generalized mother model may be utilized in various stages of automated inspection recipe generation including, but not limited to, facilitating an AST for parameter tuning, generating a review sampling map, or training a classification model.

Some embodiments are further directed to a dedicated processing controller to perform various steps associated with generation of an inspection recipe. Such a dedicated processing controller may be referred to herein as an intelligent station. For example, various post-review steps such as, but not limited to, training a classification model based on ground truth review data may be performed by this dedicated processing controller, which may free up inspection and/or review tools for further use.

By streamlining the recipe setup process and reducing the reliance on iterative SEM reviews, the disclosed systems and methods may offer advantages in terms of efficiency and accuracy compared to traditional approaches. The automated workflow may enable faster time-to-recipe while maintaining or improving defect detection capabilities. These improvements may be particularly beneficial in high-volume manufacturing environments where rapid recipe development and deployment are critical for maximizing productivity.

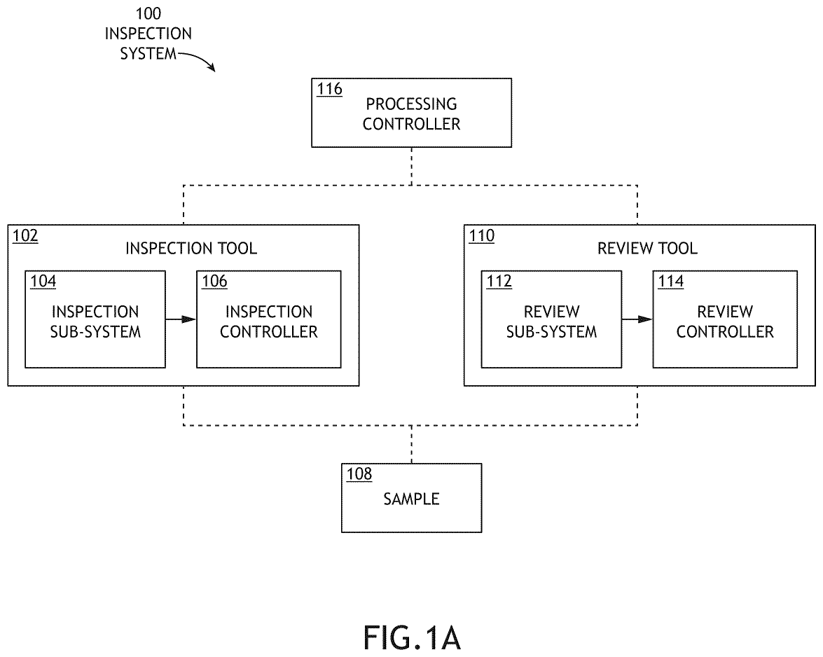

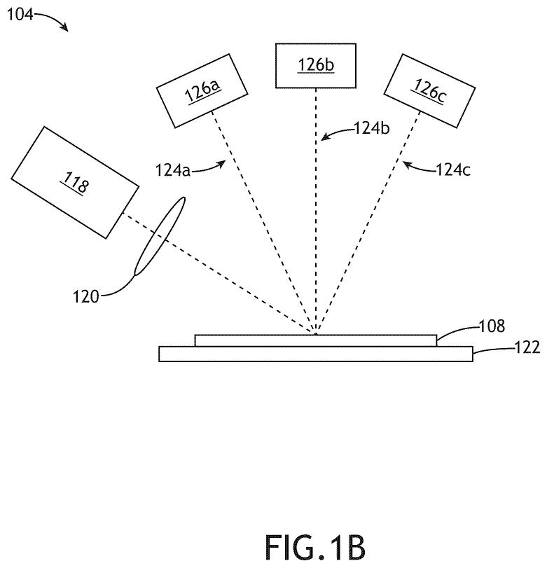

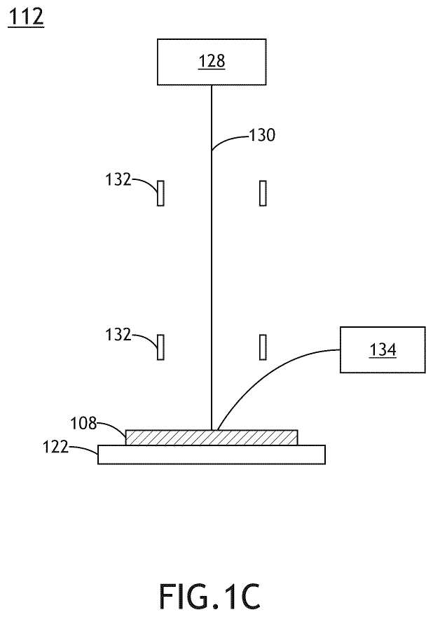

Referring now to FIGS. 1A-7, systems and methods for automated inspection recipe generation are described in greater detail, in accordance with one or more embodiments of the present disclosure.

FIG. 1A illustrates a block diagram of an inspection system 100, in accordance with some embodiments of the present disclosure.

In embodiments, the inspection system 100 includes an inspection tool 102 with an inspection sub-system 104 to generate inspection data for one or more samples 108.

The sample 108 may include a substrate formed of a semiconductor or non-semiconductor material (e.g., a wafer, or the like). For example, a semiconductor or non-semiconductor material may include, but is not limited to, monocrystalline silicon, gallium arsenide, and indium phosphide. The sample 108 may further include one or more layers disposed on the substrate. For example, such layers may include, but are not limited to, a resist, a dielectric material, a conductive material, and/or a semiconductive material. Many different types of such layers are known in the art, and the term sample as used herein is intended to encompass a sample on which all types of such layers may be formed. One or more layers formed on a sample 108 may be patterned or unpatterned. For example, a sample may include a plurality of dies, each having repeatable patterned features. Formation and processing of such layers of material may ultimately result in completed devices. Many different types of devices may be formed on a sample, and the term sample as used herein is intended to encompass a sample on which any type of device known in the art is being fabricated. The systems and methods disclosed herein may be broadly suitable for any type of devices or components including, but not limited to, integrated circuit devices, automotive devices, camera sensors, or the like.

The inspection sub-system 104 may generate inspection data of a sample 108 using any suitable technique. For example, the inspection sub-system 104 may be an imaging system that may generate one or more images of the sample 108 (e.g., darkfield images, brightfield images, or the like). In some cases, the inspection sub-system 104 may be an optical imaging system suitable for high-volume manufacturing (HVM) that generates images. Non-limiting examples of an inspection tool 102 include Voyager or Puma tools from KLA Corporation.

In embodiments, the inspection system 100 includes a review tool 110 with a review sub-system 112 to review selected locations on a sample 108. In some cases, the review sub-system 112 may have a higher resolution but a slower throughput than the inspection sub-system 104. For example, the review sub-system 112 may include, but is not limited to, a scanning electron microscope (SEM). In this way, review data from the review tool 110 may operate as ground truth data that may be used to train defect detection models to identify defects from the HVM-suitable inspection tool 102.

The inspection system 100 may include one or more controllers integrated within and/or communicatively coupled with the inspection tool 102 and/or the review tool 110. For example, FIG. 1A depicts a non-limiting configuration of an inspection system 100 with an inspection controller 106 associated with the inspection tool 102, a review controller 114 associated with the review tool 110, and a processing controller 116 communicatively coupled with the inspection tool 102 and/or the review tool 110. More generally, the inspection system 100 may include any number of controllers integrated within and/or communicatively coupled with any components of the inspection system 100 or external components.

Any of the controllers of the inspection system 100 (e.g., the inspection controller 106, the review controller 114, the processing controller 116, or any other controllers) may include one or more processors configured to execute program instructions maintained on memory, or a memory medium. In this regard, the one or more processors may execute any of the various process steps described throughout the present disclosure.

The one or more processors of any controller may include any processor or processing element known in the art. For the purposes of the present disclosure, the term “processor” or “processing element” may be broadly defined to encompass any device having one or more processing or logic elements (e.g., one or more micro-processor devices, one or more application specific integrated circuit (ASIC) devices, one or more field programmable gate arrays (FPGAs), or one or more digital signal processors (DSPs)). In this sense, the one or more processors may include any device configured to execute algorithms and/or instructions (e.g., program instructions stored in memory). In some embodiments, the one or more processors may be embodied as a desktop computer, mainframe computer system, workstation, image computer, parallel processor, networked computer, or any other computer system configured to execute a program configured to operate or operate in conjunction with the inspection system 100, as described throughout the present disclosure.

The memory may include any storage medium known in the art suitable for storing program instructions executable by the associated one or more processors. For example, the memory may include a non-transitory memory medium. By way of another example, the memory may include, but is not limited to, a read-only memory (ROM), a random-access memory (RAM), a magnetic or optical memory device (e.g., disk), a magnetic tape, a solid-state drive and the like. It is further noted that memory may be housed in a common controller housing with the one or more processors. In some embodiments, the memory may be located remotely with respect to the physical location of the one or more processors and controller. For instance, the one or more processors of the controller may access a remote memory (e.g., server), accessible through a network (e.g., internet, intranet and the like).

In embodiments, computational and/or control tasks may be implemented by any controller or combination of controllers within the inspection system 100 including, but not limited to, the inspection controller 106, the review controller 114, or the processing controller 116. In some cases, different tasks may be performed by different controllers. As an illustration, the inspection controller 106 may perform tasks related to the operation of and/or analysis of data from the inspection sub-system 104, the review controller 114 may perform tasks related to the operation of an/or analysis of data from the review sub-system 112, and the processing controller 116 may perform post-processing operations for generating an inspection recipe based on data from the inspection tool 102 and/or the review tool 110. As another illustration, the processing controller 116 may perform steps such as, but not limited to, model generation, model training, or model implementation for the inspection tool 102 and/or the review tool 110. In this way, although FIG. 1A shows a configuration where the inspection tool 102 and the review tool 110 each have dedicated controllers, the system may generally have any number of controllers associated with any components and/or dedicated controllers. In some cases, the one or more controllers of the inspection system 100 may comprise a single controller that performs the functions of the inspection controller 106, review controller 114, and processing controller 116.

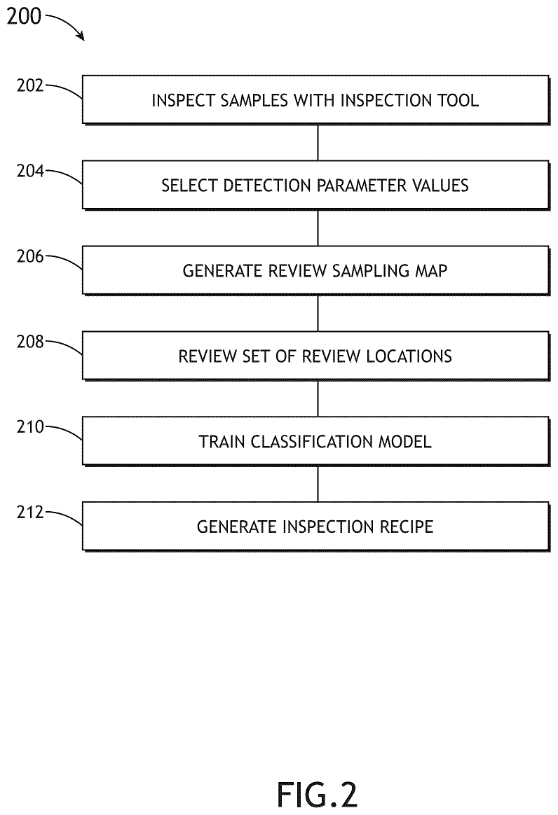

Referring now to FIGS. 2-7, a method for automated recipe generation is described, in accordance with one or more embodiments of the present disclosure.

FIG. 2 is a flow diagram illustrating steps performed in a method 200 for automated inspection recipe generation. Applicant notes that the embodiments and enabling technologies described previously herein in the context of the inspection system 100 should be interpreted to extend to the method 200. For example, any of the steps of the method 200 may be performed directly or indirectly (e.g., by generating control signals to direct another component to perform a step) by any of the controllers of the inspection system 100 alone or in combination. It is further noted, however, that the method 200 is not limited to the architecture of the inspection system 100.

The method 200 may include a step 202 of inspecting one or more samples with an inspection tool to generate inspection data. When performed with the inspection system 100, this step 202 may be implemented with the inspection tool 102 (e.g., the inspection sub-system 104 of the inspection tool 102). This step may be performed by any type of inspection tool including, but not limited to, an optical inspection tool. For example, an optical inspection tool may generate one or more images using any imaging technique including, but not limited to, darkfield imaging or brightfield imaging.

The inspection data may have any format suitable for including information indicative of the presence or absence of one or more defects. For example, the inspection data may be in a format suitable for comparison with reference data known to be free of defects using a detection model.

In embodiments, a detection model may identify potential defects, referred to herein as defect events) on the one or more samples 108 by comparing the inspection data to reference data and applying thresholds associated with the detection parameters. As an illustration in the context of an image-based detection model, the detection model may compare pixel intensities or other image characteristics between corresponding regions of an inspection image (e.g., an image of a portion of a sample 108 being inspected) and a reference image (e.g., a real or simulated image of a corresponding portion of the sample 108 known to be free of defects). The detection model may then apply processing steps such as, but not limited to, filtering, clustering, or classification steps to distinguish probable DOIs from nuisance events, where the operation of these steps may be controlled by various detection parameters. For example, the detection parameters may define thresholds or other controls that determine whether variations between the inspection data and reference data are classified as potential defects.

In some cases, the inspection data received in step 202 may correspond to or may be used to generate a “hot scan” of the one or more samples 108. A hot scan may refer to an inspection process where the inspection sub-system 104 and/or the detection model are configured to capture a wide range of potential defects or anomalies that may be at or near a noise floor of the sample 108 and/or the inspection sub-system 104, including those that may later be classified as DOIs or nuisances. For example, the detection model may run with a default set of detection parameters that provide high sensitivity to a wide range of defects (e.g., low thresholds). For this reason, the hot scan may also be referred to as a default scan. This approach may provide a comprehensive dataset for subsequent analysis and parameter optimization steps in the method 200.

In some cases, though not explicitly shown in FIG. 2, the method 200 may also implement a neural network model, which may be referred to as a mother model, to perform an initial classification of defect events associated with the inspection data generated in step 202. In some cases, the neural network model may perform an initial classification of defect events associated with a hot scan or default scan.

The neural network model may assign probabilities or confidence scores for various defect categories. The detection model may classify the defect events into any number or type of categories (e.g., preliminary classes). As an illustration, the neural network model may classify defect events in the hot scan into high-confidence DOIs, low-confidence DOIs, high-confidence nuisance events, and low-confidence nuisance events. As another illustration, the neural network model may classify defect events by defect type. However, these are merely illustrations and not limiting. The neural network model (e.g., the mother model) may classify defect events from the hot scan into any number or type of classes.

The neural network model may be trained using a diverse set of training data comprising historical inspection data from multiple layers and defect types. In this way, the neural network model may be generalized beyond the current layer of a sample 108 being inspected and/or the particular process used. This training data may include, but is not limited to, images of known defects of interest (DOIs) and nuisances, along with associated metadata such as defect size, location, and classification. The model may utilize a deep learning architecture, such as a convolutional neural network (CNN), to extract relevant features from the input data and learn to distinguish between various DOIs and nuisances.

The method 200 may include a step 204 of selecting values of detection parameters for the detection model with an automated sensitivity tuner (AST) that provide selected detection rates of probable defects of interest and probable nuisances. An AST is generally described in U.S. patent application Ser. No. 19/289,391 filed on Aug. 4, 2025, which is incorporated herein by reference in its entirety. When performed with the inspection system 100, this step 204 may be implemented by any of the controllers of the inspection system 100 alone or in combination.

As described previously herein, a detection model may identify potential defects (e.g., defect events) by comparing the inspection data to reference data and applying thresholds associated with the detection parameters. In this way, the detection parameters may control the sensitivity of the detection model to certain types of defects.

It is contemplated herein that the defect detection parameters may have many interrelated effects such that determining suitable values for these parameters may be complex, tedious, and time consuming. For example, a detection model may have five, ten, or more detection parameters that may provide interrelated effects. As a result, the task of selecting suitable values of the detection parameters suitable for distinguishing probable DOIs from probable nuisances is multi-dimensional selection problem (e.g., an n-dimensional selection problem for a detection model with n parameters that may be tuned).

When performed manually, this process typically requires multiple iterations of hot scans and/or review steps. In contrast, the AST may automate the process and may require little or no user interaction. In embodiments, an AST implements a machine learning technique to evaluate a parameter space (e.g., an n-dimensional parameters space) associated with the detection parameters for a selected detection model to determine values of the detection parameters that distinguish between probable DOIs and probable nuisance events.

In embodiments, the AST generates a receiver operating characteristic (ROC) curve describing possible operating points of the detection model. For example, an ROC curve may plot a retention rate of probable DOIs as a function of total number of defect events, where each point on the ROC corresponds to the operation of the detection model with different values of the detection parameters (and thus different operating thresholds) as determined by the AST. In this way, each point on the ROC (e.g., each operating point of the detection model) may be the result of an n-dimensional analysis of the detection parameter space (e.g., n detection parameters being tuned).

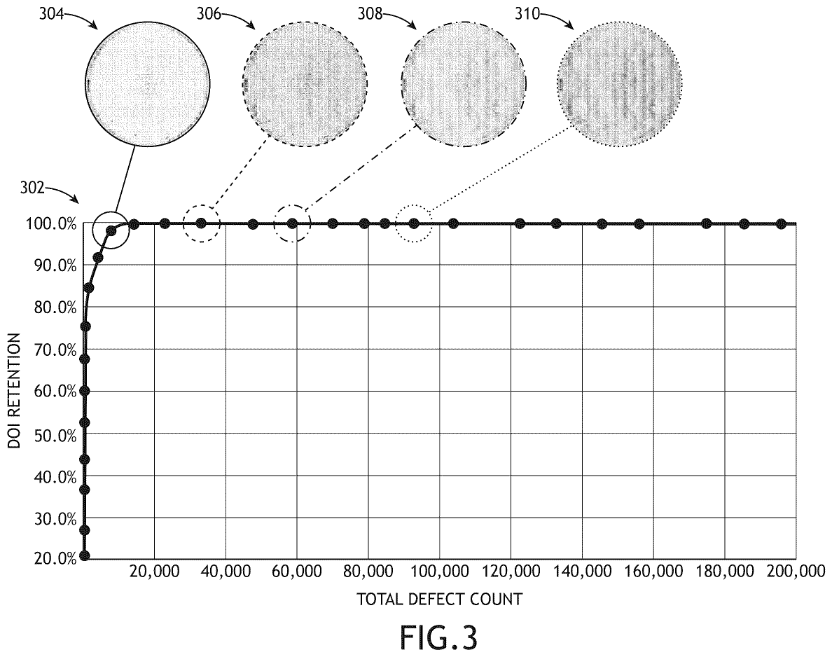

FIG. 3 illustrates a receiver operating characteristic (ROC) curve 302, in accordance with one or more embodiments of the present disclosure. In FIG. 3, the defect retention rate (e.g. a retention rate of probable DOIs) is plotted relative to total defect count (e.g., a total number of events identified by a detection model). It may be the case that a defect model may not perfectly distinguish probable DOIs from probable nuisances. Rather, a defect model may typically output defect events that include both probable DOIs as well as probable nuisances and, in some cases, may identify many more probable nuisances than probable DOIs. In most cases, increasing the total defect count from the defect model results in higher percentages of probable DOIs. Further, as shown in FIG. 3, the ROC curve may show a rapid increase in DOI retention rate followed by a more gradual increase until or approaching 100%.

FIG. 3 additionally depicts insets associated with defect maps associated with selected operating points of the ROC curve 302. In particular, FIG. 3 depicts a first defect map 304, a second defect map 306, a third defect map 308, and a fourth defect map 310, each at increasing total defect counts as seen by the increasing density in the associated defect maps.

It is contemplated herein that generating an ROC curve may allow for the dynamic selection of a desired performance level of the detection model based on the requirements of any particular application. In particular, each point on the ROC curve represents a different balance between number of total defect events (e.g., total defect count) and number of probable DOIs captured by particular settings of the detection model.

In some applications, the step 204 may include presenting the ROC curve to a user (e.g., via a display device), receiving input from the user about a selected operating point, and providing the values of the detection parameters associated with the user-selected operating point. In some cases, the step 204 may include selecting an operating point according to one or more criteria such as, but not limited to, a DOI detection rate (e.g., retention rate) equal to or above a selected value, a total defect count equal to or below a selected value, or a nuisance detection rate equal to or below a selected value. In this way, the inspection system 100 and/or a user may define an algorithm or a set of criteria to select the operating point in an automated way.

When generating the ROC curve, the AST relies on some classification of defect events into probable DOIs or probable nuisances. The AST may utilize any combination of machine learning techniques to classify defect events when generating an ROC curve and/or providing detection parameter values associated with a selected operating point including, but not limited to, supervised learning, unsupervised learning, semi-supervised learning, or reinforcement learning. As used herein, the term “machine learning technique” refers to a computational method that uses algorithms and statistical models to enable computer systems to improve their performance on a specific task through experience. In the context of the present disclosure, machine learning techniques may include supervised learning, unsupervised learning, or reinforcement learning approaches applied to analyze inspection data and optimize detection parameters. “Supervised learning” refers to a type of machine learning where the algorithm is trained on a labeled dataset, meaning the input data is paired with corresponding output labels. “Unsupervised learning” refers to a type of machine learning where the algorithm analyzes unlabeled data to find patterns or groupings without pre-existing output labels.

For example, if ground truth data including inspection images of known DOIs and known nuisances is available, the AST may utilize a supervised machine learning technique that utilizes this ground truth data (e.g., as training data). This ground truth data may be derived from any source including, but not limited to, inspection and review of fabricated samples (e.g., with an inspection tool 102 and a review tool 110).

As another illustration, the AST may use unsupervised techniques to distinguish probable DOIs from probable nuisance events even without such ground truth data. In some embodiments, the AST may employ unsupervised machine learning techniques to distinguish probable DOIs from probable nuisance events without relying on ground truth data. The unsupervised AST may analyze the distribution of defect attributes in the multi-dimensional parameter space to identify clusters and outliers. For example, the AST may utilize clustering algorithms such as, but not limited to, k-means or Gaussian mixture models to group similar defects together. Outliers that do not fit well into any cluster may be considered as potential DOIs, as they may represent rare or unusual defects.

For example, the AST may assign an outlier ranking to each of the defect events, which may operate as an unsupervised metric for ranking outlier events. The AST may then classify the defect events as probable defects of interest or probable nuisances based on the outlier rankings. As described above, these classifications may be used when performing multi-parameter optimization to select values of detection parameters when generating an ROC curve.

The outlier rankings may be based on any criteria. For example, the outlier rankings may be associated with defect density in a cluster analysis, where defect events in relatively low-density regions receive a higher outlier ranking than defect events in relatively high-density regions. As another example, the outlier rankings may be associated with one or more distances of particular defect events from one or more clusters. In this case, defect events located relatively further from the clusters may be assigned higher outlier rankings than defect events located relatively closer to or within any of the clusters.

The AST may then adjust detection parameters to optimize the separation between these identified clusters and outliers. This unsupervised approach may be particularly useful for, but not limited to, scenarios where labeled training data is unavailable or when exploring new defect types that have not been previously characterized. The unsupervised AST may adapt to evolving defect patterns and potentially identify novel defect classes that might be overlooked by supervised methods relying on predefined categories.

As another illustration, the AST may use semi-supervised techniques that combine both available ground truth data and unsupervised techniques to distinguish probable DOIs.

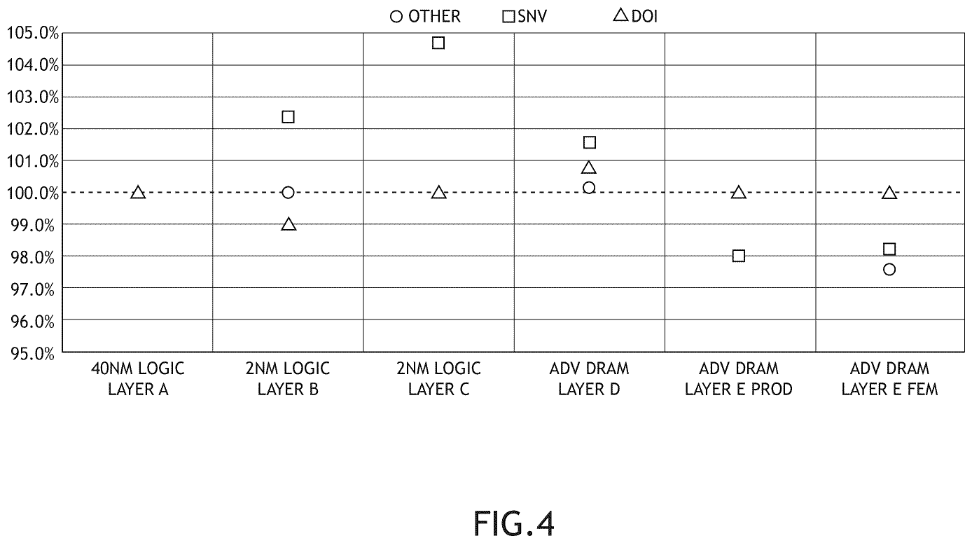

FIG. 4 illustrates a plot comparing unsupervised and supervised automated sensitivity tuner configurations, in accordance with one or more embodiments of the present disclosure. In particular, FIG. 4 shows capture rate ratios of DOI, nuisance (SNV), and other non-critical defect events from defect paretos obtained using unsupervised and supervised AST configurations for six different defect types. As shown in FIG. 4, the unsupervised AST configuration may provide roughly equivalent and sometimes superior performance than the supervised configuration. In this way, unsupervised AST, which does not require the generation of ground truth data, may provide efficient and automated selection of detection parameters to distinguish probable DOIs from probable nuisance events.

Referring again to FIG. 2, the method 200 may include a step 206 of generating a review sampling map including locations on a sample 108 to review with a review tool 110. As described previously herein, it may be the case that the detection model tuned by the AST may still identify some nuisance events in addition to actual DOIs. In step 206, selected locations on the sample 108 may be reviewed to generate ground truth review data that may be used to further refine the detection model and/or a classification model (e.g., a nuisance reduction model) for use in an inspection recipe. In the case of the inspection system 100, the step 206 may be implemented by any controller or combination of controllers including, but not limited to, the inspection controller 106, the review controller 114, or the processing controller 116.

The review sampling map generated in step 206 may generally include any number of the defect events identified by the detection model using the detection parameters tuned by the AST in step 204. However, in many applications, the review sampling map is limited to a small fraction of these defect events due to factors such as, but not limited to, a relatively slow throughput of the review tool 110. Accordingly, it may be desirable to preferentially select not only the defect events that correspond to probable DOIs but a wide range of DOIs. In this way, the classification model trained by the review data may identify these wide range of DOIs.

In embodiments, the step 206 may incorporate a discovery sampling technique that may leverage various sources of information (e.g., a priori knowledge) and/including, but not limited to, values of the detection parameters generated by the AST (e.g., from step 204), outputs from a mother model (e.g., defect classifications, confidence levels, or the like), a ranking of defects (e.g., based on the mother model and/or the AST), information about die geometry (e.g., care areas, or the like), or a wafer map. Further, the discovery sampling technique in step 206 may determine the review sampling map based on one or more diversity weights that may optionally be set by a user. For example, the diversity weights may control the impact of diversity factors (e.g., diversity preferences) on the review sampling map, where the diversity factors may include, but are not limited to, diversity of sampled location across an entire sample of the one or more samples, diversity of samples across different defined regions of the one or more samples, or class diversity associated with different classifications and/or confidence levels of defect events. As another example, diversity preference may include suppression of unwanted defect types (e.g., large defects, obvious defects, or the like), which may encourage diversity by not wasting review time for these non-critical defects and instead generating a review sampling map with a high hit rate of key DOIs of interest. Discovery sampling based on diversity weights is generally described in U.S. patent application Ser. No. 19/289,733 filed on Aug. 4, 2025, which is incorporated herein by reference in its entirety.

In some cases, the one or more processors of the inspection system may be configured to generate the review sampling map with the automated sampling model. The review sampling map generated by the automated sampling model may enable efficient use of the review tool by identifying a set of review locations most likely to provide valuable information about defects of interest on the one or more samples.

The method 200 may include a step 208 of reviewing the set of review locations in the review sampling map on the one or more samples 108 with the review tool 110 to generate ground truth data. The ground truth data may include defect classifications of the set of review locations. When performed with the inspection system 100, this step 208 may be implemented with the review tool 110.

The method 200 may include a step 210 of training a classification model to identify defects of interest (DOIs) from a set of potential defects identified by the detection model. The classification model may be trained based at least on ground truth data generated by the review tool 110 in step 208. When performed with the inspection system 100, this step 210 may be implemented by any of the controllers of the inspection system 100 alone or in combination.

In some cases, the classification model may be an Intelligent Classification Engine (ICE), a nuisance reduction model, or a nuisance optimization model. The purpose of the classification model may be to distinguish DOIs from nuisances, providing an output tailored to DOIs while filtering out nuisances. In some cases, the classification model may further categorize DOIs into different classes.

The classification model (e.g., the ICE) may be structured as a random forest model in some implementations. A random forest model may consist of multiple decision trees, each trained on a subset of the available data and features. In the context of defect classification, these decision trees may be trained using various attributes derived from the inspection images, detection parameters, and ground truth data. The random forest structure may allow the ICE to consider a wide range of features and their interactions, potentially improving its ability to distinguish between DOIs and nuisances.

The classification model may utilize various sources of information in addition to the ground truth data from step 206. For example, the classification model may incorporate outputs from the detection model, detection parameters for the detection model selected by the automated sensitivity tuner (AST), outputs from the mother model, outputs from other classifiers, die-level information, or wafer-level information.

The method 200 may include a step 212 of generating an inspection recipe. When performed with the inspection system 100, this step 212 may be implemented by any of the controllers of the inspection system 100 alone or in combination. For example, the processing controller 116 may generate the inspection recipe.

The inspection recipe may include any models and/or associated configuration parameters suitable for identifying and/or classifying defects based on inspection data (e.g., from an inspection tool 102). For example, the inspection recipe may include the detection model and/or the tuned values of the detection parameters identified by the AST in step 202. As another example, the inspection recipe may include the classification model and/or any configuration parameters developed in step 208.

In some cases, the inspection recipe may also include additional components or parameters. For example, the inspection recipe may specify regions of interest on the sample 108 to be inspected, imaging modes or settings for the inspection sub-system 104, or post-processing steps to be applied to the inspection data.

The generated inspection recipe may be stored in memory associated with the inspection system 100 and may be retrieved and applied by the inspection tool 102 when inspecting subsequent samples.

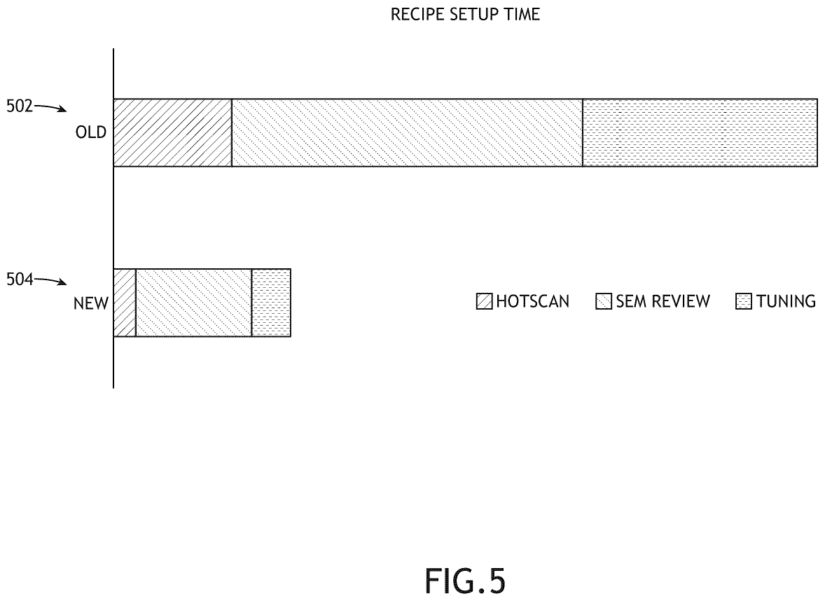

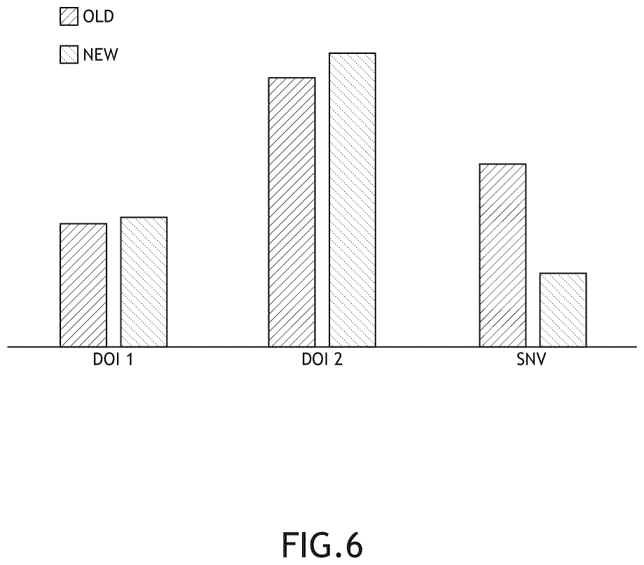

Referring now to FIGS. 5-6, efficiency and performance of the systems and methods disclosed herein relative to traditional techniques are described.

FIG. 5 illustrates a comparison of recipe setup time between manual and automated approaches, in accordance with one or more embodiments of the present disclosure. A first bar chart 502 shows the recipe setup time for a manual process, including portions for hotscan generation, SEM review, and tuning phases. A second bar chart 504 displays the recipe setup time for an automated process as disclosed herein (e.g., as described with respect to the inspection system 100 and/or the method 200. As depicted, the automated process as disclosed herein reduces the time for each of these phases to provide a substantially reduced overall recipe setup time.

The first bar chart 502 and the second bar chart 504 may illustrate the efficiency improvements provided by the automated inspection recipe generation method described herein. In some cases, the automated process may significantly reduce the overall recipe setup time compared to the manual process. The reduction in setup time may be attributed to several factors, including the elimination of multiple iterative SEM review cycles and the automation of parameter tuning steps.

FIG. 6 illustrates a bar graph comparing manual and automated detection results for three different defect event categories, in accordance with one or more embodiments of the present disclosure. In particular, FIG. 6 illustrates paretos associated with two different classes of DOIs (labeled DOI 1 and DOI 2) as well as nuisance events (labeled as SNV). As shown in FIG. 6, the performance of an inspection recipe generated through the automated systems and methods disclosed herein provides higher defect detection rates (e.g., as evidenced by the higher bar height) than a manual process, while also providing fewer nuisances than the manual process. In this way, the inspection recipe generated using the automated process as disclosed herein better identifies key DOIs while filtering out nuisance events than the manual approach.

Techniques for distributing the implementation of various steps of the method 200 between different controllers is described in greater detail. In a general sense, the steps of the method 200 may be performed by a single controller or distributed between multiple controllers.

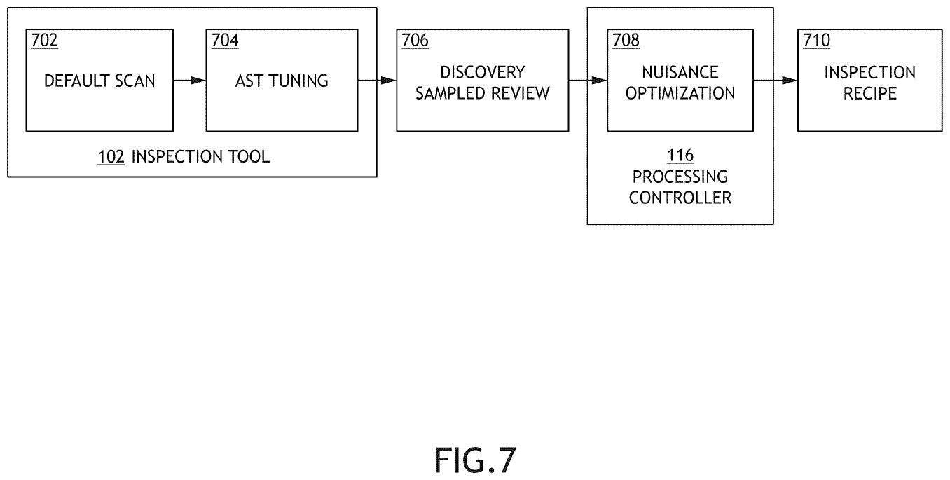

FIG. 7 illustrates a flowchart of one process for generating an inspection recipe incorporating a dedicated processing controller 116, in accordance with one or more embodiments of the present disclosure. In this configuration, a default scan 702 (e.g., associated with step 202) and AST tuning 704 (e.g., associated with step 204) may be performed by the inspection tool 102 (e.g., the inspection controller 106 of the inspection tool 102). A discovery sampled review 706 may be performed by the review tool 110. Subsequent steps, including nuisance optimization 708 (e.g., generation and/or training of a classification model in step 210) and generation of an inspection recipe 710 (e.g., in step 212), may be performed on the processing controller 116. Although not explicitly shown, the step 206 of generating the sampling review map may be performed by any of the controllers including, but not limited to, the inspection controller 106 of the inspection tool 102, the review controller 114 of the review tool 110, or the processing controller 116.

In this configuration, the processing controller 116 may serve as an integrated hub for model generation, inference and data management, which may be separate from the inspection tool 102 and optionally referred to as an intelligent station. This configuration may free up the inspection tool 102 for other tasks after the default scan 702 and AST tuning 704 are completed. The data may flow to the review tool 110 for the discovery sampled review 706, but the inspection tool 102 may continue running production with other samples 108. In some cases, steps such as the automated selection of detection parameters may optionally be performed on the inspection tool 102 rather than the processing controller 116. This flexibility in task distribution may allow for optimization based on available computational resources and workflow requirements.

The processing controller 116 may facilitate seamless data fetching and labeling operations from both the inspection tool 102 and review tool 110 and may efficiently gather all required images within a unified workspace to perform nuisance optimization techniques. Beyond basic data management, the processing controller 116 may offer offline inference capabilities that may enable users to validate optimization models using existing lot results, thereby potentially eliminating the need to conduct additional verification scans on the inspection tool itself. Furthermore, the processing controller 116 may enhance system-wide integration by facilitating the distribution of newly generated nuisance optimization models to all inspection tools through a recipe distribution server (RDS) infrastructure. This approach may effectively transition tuning operations from the inspection tool 102 to an offline server environment, potentially improving tool utilization time for inspection activities.

Referring generally to FIGS. 1A-7, the systems and methods disclosed herein may used to generate an inspection recipe for any type of inspection tool 102 using review from any type of review tool 110, along with any associated inspection or review models.

FIG. 1B illustrates a block diagram of an inspection sub-system 104, in accordance with one or more embodiments of the present disclosure. For example, the inspection sub-system 104 may be a non-limiting illustration of a darkfield optical sub-system suitable for implementing the step 202.

In embodiments, the inspection sub-system 104 includes an illumination source 118 configured to generate an illumination beam. The illumination source 118 may include any type of illumination source known in the art suitable for generating an optical illumination beam. The illumination beam may have any spectrum such as, but not limited to, extreme ultraviolet (EUV) wavelengths, ultraviolet (UV) wavelengths, visible wavelengths, or infrared (IR) wavelengths. Further, the illumination source 118 may be a broadband source, a narrowband source, and/or a tunable source.

In embodiments, the illumination source 118 includes a broadband plasma (BBP) illumination. In this configuration, the illumination beam may include radiation emitted by a plasma. For example, a BBP illumination source 118 may include, but is not required to include, one or more pump sources (e.g., one or more lasers) configured to focus into the volume of a gas, causing energy to be absorbed by the gas in order to generate or sustain a plasma suitable for emitting radiation. Further, at least a portion of the plasma radiation may be utilized as the illumination beam.

In embodiments, the illumination source 118 may include one or more lasers. For instance, the illumination source 118 may include any laser system known in the art capable of emitting radiation in the infrared, visible, or ultraviolet portions of the electromagnetic spectrum.

The illumination source 118 may further produce an illumination beam having any temporal profile. For example, the illumination source 118 may produce continuous-wave (CW) illumination beam, pulsed illumination beam, or modulated illumination beam. Additionally, the illumination beam may be delivered from the illumination source 118 via free-space propagation or guided light (e.g., an optical fiber, a light pipe, or the like).

The inspection sub-system 104 may further include various components to direct the illumination beam to the sample 108 such as, but not limited to, mirrors, lenses (e.g., lens 120 in FIG. 1B), diverters, filters (e.g., spatial and/or temporal filters), diffusers, homogenizers, apodizers, beamsplitters, or the like. Further, such components may be reflective elements or transmissive elements.

In embodiments, sample 108 is disposed on a stage assembly 122 to facilitate movement of sample 108. Stage assembly 122 may include any actuators known in the art including, but not limited to, an X-Y stage, an R-θ stage, a tip/tilt stage, or the like. Further, the stage assembly 122 is capable of adjusting the height of sample 108 during inspection or imaging to maintain focus on the sample 108.

In embodiments, inspection sub-system 104 includes one or more detection channels. The one or more detection channels may include one or more detectors configured to collect illumination scattered from the sample 108 and acquire images of the sample 108. For example, as shown in FIG. 1B, inspection sub-system 104 may include a first detection channel 124a including a first detector 126a, a second detection channel 124b including a second detector 126b, and a third detection channel 124c including a third detector 126c. In the configuration of FIG. 1B, the first detector 126a, the second detector 126b, and the third detector 126c are positioned to generate darkfield images based on light that is scattered and/or diffracted by the sample 108, where each detector generates an image with light from a different range of collection angles.

The one or more detectors may include any type of sensor suitable for capturing scattered light from the sample 108 such as, but not limited to, complementary metal-oxide-semiconductor (CMOS) sensors, charge-coupled devices (CCDs), time delay integration (TDI) sensors, avalanche photodiodes (APDs), photomultiplier tubes (PMTs), or hybrid detectors combining multiple technologies.

Although not shown, the inspection tool 102 may include one or more optical elements configured to collect illumination scattered from the sample 108 and direct the illumination to the one or more detectors. The one or more optical elements may include any optical elements known in the art including, but not limited to, mirrors, lenses, diverters, filters (e.g., spatial and/or temporal filters), diffusers, homogenizers, apodizers, beamsplitters, or the like.

While FIG. 1B illustrates an inspection sub-system 104 including three detectors configured to acquire patch images along three scattering angles, this is not to be regarded as a limitation of the present disclosure, unless noted otherwise herein. In this regard, it is contemplated that inspection sub-system 104 may be arranged in any configuration including, but not limited to, a one-detection-channel configuration, a two-detection-channel configuration, a three-detection-channel configuration, a five-detection-channel configuration, and the like. Comparisons between various channel configurations will be discussed in further detail herein.

FIG. 1C illustrates a block diagram of a review sub-system 112, in accordance with one or more embodiments of the present disclosure. For example, FIG. 1C may depict a non-limiting example of a SEM review sub-system 112.

In embodiments, the review sub-system 112 includes a particle source 128 to generate a particle beam 130. The particle source 128 may include any particle source known in the art suitable for generating a particle beam 130. For example, the particle source 128 may include, but is not limited to, an electron gun or an ion gun. In another embodiment, the particle source 128 is configured to provide a particle beam with a tunable energy. For example, a particle source 128 including an electron source may, but is not limited to, provide an accelerating voltage in the range of 0.1 kV to 30 kV. As another example, a particle source 128 including an ion source may, but is not required to, provide an ion beam with an energy in the range of 1 to 50 keV.

In another embodiment, the particle control elements 132 includes one or more particle focusing elements. For example, the one or more particle focusing elements may include, but are not limited to, a single particle focusing element or one or more particle focusing elements forming a compound system. In another embodiment, the one or more particle focusing elements include an objective lens configured to direct the particle beam 130 to the sample 108. Further, the one or more particle focusing elements may include any type of electron lenses known in the art including, but not limited to, electrostatic, magnetic, uni-potential, or double-potential lenses. It is noted herein that the description of a voltage contrast imaging inspection system as depicted in FIG. 1C and the associated descriptions above are provided solely for illustrative purposes and should not be interpreted as limiting. For example, the review sub-system 112 may include any excitation source known in the art suitable for generating review data on a sample 108. In another embodiment, the review sub-system 112 includes two or more particle beam sources (e.g., electron beam sources or ion beam sources) for the generation of two or more particle beams. In a further embodiment, the review sub-system 112 may include one or more components (e.g., one or more electrodes) configured to apply one or more voltages to one or more locations of the sample 108. In this regard, the review sub-system 112 may generate voltage contrast imaging data.

In another embodiment, the review sub-system 112 includes one or more particle detectors 134 to image or otherwise detect particles emanating from the sample 108. In one embodiment, the particle detector 134 includes an electron collector (e.g., a secondary electron collector, a backscattered electron detector, or the like). In another embodiment, the particle detector 134 includes a photon detector (e.g., a photodetector, an x-ray detector, a scintillating element coupled to photomultiplier tube (PMT) detector, or the like) for detecting electrons and/or photons from the sample surface.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected” or “coupled” to each other to achieve the desired functionality, and any two components capable of being so associated can also be viewed as being “couplable” to each other to achieve the desired functionality. Specific examples of couplable include but are not limited to physically interactable and/or physically interacting components and/or wirelessly interactable and/or wirelessly interacting components and/or logically interactable and/or logically interacting components.

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. An inspection system comprising:
one or more controllers including one or more processors configured to execute program instructions causing the one or more processors to:
receive inspection data for one or more samples from an inspection tool;
select values of detection parameters of a detection model with an automated sensitivity tuner, wherein the detection model identifies potential defect events on the one or more samples by comparing the inspection data to reference data and applying thresholds associated with the detection parameters, wherein the automated sensitivity tuner selects the values of the detection parameters to provide selected detection rates of probable defects of interest and probable nuisances;
generate a review sampling map with an automated sampling model, wherein the review sampling map includes a set of review locations on the one or more samples to review with a review tool;
train a classification model to identify defects of interest from a set of the potential defect events from the detection model based at least on ground truth data generated by the review tool; and
generate an inspection recipe, wherein the inspection recipe includes at least the values of the detection parameters for the detection model selected by the automated sensitivity tuner and the classification model.

2. The inspection system of claim 1, wherein the inspection tool comprises:
an optical inspection tool.

3. The inspection system of claim 2, wherein the inspection tool comprises:
a darkfield optical inspection tool.

4. The inspection system of claim 1, wherein the review tool comprises:
a scanning electron microscope.

5. The inspection system of claim 1, wherein the one or more processors are further configured to execute program instructions causing the one or more processors to:
label the potential defect events associated with the one or more samples identified by the detection model with preliminary classes using a neural network model trained on defect data associated with multiple defect types.

6. The inspection system of claim 5, wherein training the classification model to identify the defects of interest from the potential defect events identified by the detection model based at least on the ground truth data comprises:
training the classification model to identify the defects of interest from the potential defect events identified by the detection model based at least on the ground truth data and the preliminary classes from the neural network model.

7. The inspection system of claim 5, wherein the defect data used for training the neural network model includes data from multiple layers.

8. The inspection system of claim 1, wherein the automated sensitivity tuner includes an unsupervised model to classify the inspection data into the probable defects of interest and the probable nuisances, wherein the detection rates of the probable defects of interest and the probable nuisances are based at least in part on classifications from the unsupervised model.

9. The inspection system of claim 8, wherein the unsupervised model comprises a clustering model incorporating an outlier threshold associated with a distance of a particular inspection defect event from a cluster in a multi-dimensional parameter space including at least some of the detection parameters.

10. The inspection system of claim 1, wherein the automated sensitivity tuner is a supervised model to classify the inspection data into the probable defects of interest and the probable nuisances, wherein the detection rates of the probable defects of interest and the probable nuisances are based at least in part on classifications from the supervised model.

11. The inspection system of claim 1, wherein selecting the values of the detection parameters to provide selected detection rates of the probable defects of interest and the probable nuisances comprises a detection rate of the probable defects equal to or above a first selected percentage.

12. The inspection system of claim 1, selecting the values of the detection parameters to provide selected detection rates of the probable defects of interest and the probable nuisances further comprises a detection rate of the probable nuisances equal to or below a second selected percentage.

13. The inspection system of claim 1, wherein the automated sampling model selects the set of review locations to control relative sampling rates of different defect types according to diversity weights associated with at least one of diversity of defect class, diversity of sampled location across an entire sample of the one or more samples, or diversity of samples across different defined regions of the one or more samples.

14. The inspection system of claim 1, wherein the one or more controllers comprise:
an inspection controller associated with the inspection tool, wherein the inspection controller is configured to select the values of the detection parameters for the detection model with the automated sensitivity tuner; and
a processing controller communicatively coupled to at least one of the inspection tool or the review tool, wherein the processing controller is configured to:
generate the review sampling map with the automated sampling model;
train the classification model to identify defects of interest from the set of the potential defect events from the detection model based at least on ground truth data generated by the review tool; and
generate the inspection recipe.

15. The inspection system of claim 1, wherein the one or more controllers comprise a single controller.

16. An inspection system comprising:
an inspection tool configured to generate inspection data for one or more samples;
a review tool having a higher resolution than the inspection tool; and
one or more controllers including one or more processors configured to execute program instructions causing the one or more processors to:
receive inspection data for one or more samples from the inspection tool;
select values of detection parameters of a detection model with an automated sensitivity tuner, wherein the detection model identifies potential defect events on the one or more samples by comparing the inspection data to reference data and applying thresholds associated with the detection parameters, wherein the automated sensitivity tuner selects the values of the detection parameters to provide selected detection rates of probable defects of interest and probable nuisances;
generate a review sampling map with an automated sampling model, wherein the review sampling map includes a set of review locations on the one or more samples to review with a review tool;
train a classification model to identify defects of interest from a set of the potential defect events from the detection model based at least on ground truth data generated by a review tool; and
generate an inspection recipe, wherein the inspection recipe includes at least the values of the detection parameters for the detection model selected by the automated sensitivity tuner and the classification model.

17. The inspection system of claim 16, wherein the inspection tool comprises:
an optical inspection tool.

18. The inspection system of claim 17, wherein the inspection tool comprises:
a darkfield optical inspection tool.

19. The inspection system of claim 16, wherein the review tool comprises:
a scanning electron microscope.

20. The inspection system of claim 16, wherein the one or more controllers comprise:
an inspection controller associated with the inspection tool, wherein the inspection controller is configured to select the values of the detection parameters for the detection model with the automated sensitivity tuner; and
a processing controller communicatively coupled to at least one of the inspection tool or the review tool, wherein the processing controller is configured to:
generate the review sampling map with the automated sampling model;
train the classification model to identify defects of interest from the set of the potential defect events from the detection model based at least on ground truth data generated by the review tool; and
generate the inspection recipe.

21. The inspection system of claim 16, wherein the one or more controllers comprise a single controller.

22. An inspection method comprising:
inspecting one or more samples with an inspection tool to generate inspection data;
selecting values of detection parameters for a detection model with an automated sensitivity tuner, wherein the detection model identifies potential defect events on the one or more samples by comparing the inspection data to reference data and applying thresholds associated with the detection parameters, wherein the automated sensitivity tuner selects the values of the detection parameters to provide selected detection rates of probable defects of interest and probable nuisances;
generating a review sampling map with an automated sampling model, wherein the review sampling map includes a set of review locations on the one or more samples to review with a review tool;
reviewing the set of review locations in the review sampling map on the one or more samples with the review tool to generate ground truth data, wherein the ground truth data includes defect classifications of the set of review locations;
training a classification model to identify defects of interest from a set of the potential defect events from the detection model based at least on the ground truth data; and
generating an inspection recipe, wherein the inspection recipe includes at least the values of the detection parameters for the detection model selected by the automated sensitivity tuner and the classification model.

23. The inspection method of claim 22, further comprising:
labeling the potential defect events associated with the one or more samples identified by the detection model with preliminary classes using a neural network model trained on defect data associated with multiple defect types.

24. The inspection method of claim 23, wherein training the classification model to identify the defects of interest from the potential defect events from the detection model based at least on the ground truth data comprises:
training the classification model to identify the defects of interest from the potential defect events from the detection model based at least on the ground truth data and the preliminary classes from the neural network model.

25. The inspection method of claim 23, wherein the defect data used for training the neural network model includes data from multiple layers.

26. The inspection method of claim 22, wherein the automated sensitivity tuner includes an unsupervised model to classify the inspection data into the probable defects of interest and the probable nuisances, wherein the detection rates of the probable defects of interest and the probable nuisances are based at least in part on classifications from the unsupervised model.

27. The inspection method of claim 22, wherein the automated sensitivity tuner is a supervised model to classify the inspection data into the probable defects of interest and the probable nuisances.

28. The inspection method of claim 27, wherein selecting the values of the detection parameters to provide selected detection rates of the probable defects of interest and the probable nuisances comprises a detection rate of the probable defects equal to or above a first selected percentage.

29. The inspection method of claim 22, wherein selecting the values of the detection parameters to provide selected detection rates of the probable defects of interest and the probable nuisances further comprises a detection rate of the probable nuisances equal to or below a second selected percentage.

30. The inspection method of claim 22, wherein the automated sampling model selects the set of review locations to control relative sampling rates of different defect types according to diversity weights associated with at least one of diversity of defect class, diversity of sampled location across an entire sample of the one or more samples, or diversity of samples across different defined regions of the one or more samples.

31. The inspection method of claim 22, wherein an inspection controller associated with the inspection tool performs selecting the values of the detection parameters for the detection model with the automated sensitivity tuner, wherein a processing controller communicatively coupled with at least one of the inspection tool or the review tool performs steps of:
generating the review sampling map with the automated sampling model;
training the classification model to identify defects of interest from the set of the potential defect events from the detection model based at least on ground truth data generated by the review tool; and
generating the inspection recipe.
